(19) United States
(12) Patent Application Publication
(10) Pub. No.: US 2009/0252974 A1
(43) Pub. Date: Oct. 8, 2009

(54) EPITAXIAL WAFER HAVING A HEAVILY DOPED SUBSTRATE AND PROCESS FOR THE PREPARATION THEREOF

(75) Inventors: Robert J. Falster, London (GB); Vladimir V. Voronkov, Merano (IT); Luca Moiraghi, Milano (IT); DongMyun Lee, Lake Saint Louis, MO (US); Chanrae Cho, Austin, TX (US); Marco Ravani, Novara (IT)

Correspondence Address: Richard A. Schuth (MEMC);Armstrong Teasdale LLP, One Metropolitan Square, Suite 2600, St. Louis, MO, 63102-2740, US

(73) Assignee: MEMC ELECTRONIC MATERIALS, INC., St. Peters, MO (US)

(21) Appl. No.: 12/486,569

(22) Filed: Jun. 17, 2009

Related U.S. Application Data
(63) Continuation of application No. 11/771,683, filed on Jun. 29, 2007.

(51) Int. Cl. H01L 21/36; B32B 9/04

(52) U.S. Cl. 428/446; 438/478; 438/492; 257/E21.461

(57) ABSTRACT

This invention generally relates to a process for suppressing silicon self-interstitial diffusion near the substrate/epitaxial layer interface of an epitaxial silicon wafer having a heavily doped silicon substrate and a lightly doped silicon epitaxial layer. Interstitial diffusion into the epitaxial layer is suppressed by a silicon self-interstitial sink layer comprising dislocation loops.

### CROSS-REFERENCE TO RELATED APPLICATION

This application is a Continuation of U.S. Ser. No. 11/771,683, filed Jun. 29, 2007, the entire contents of which are hereby incorporated by reference.

### BACKGROUND OF THE INVENTION

The present invention generally relates to epitaxial semiconductor structures, especially epitaxial silicon wafers used in the manufacture of electronic components, and to methods for their preparation. More specifically, the epitaxial structures comprise a single crystal silicon substrate that is heavily doped with an N-type dopant (N+) or a P-type dopant (P+) and an epitaxial layer which is lightly doped with an N-type or P-type dopant, wherein the heavily doped substrate comprises a region near the lightly doped epitaxial layer having a high concentration of structures capable of suppressing or preventing silicon interstitial diffusion toward the epitaxial layer, thereby reducing silicon interstitial diffusion into said epitaxial layer.

Single crystal silicon, the starting material for most processes for the fabrication of semiconductor electronic components, is commonly prepared by the Czochralski process, wherein a single seed crystal is immersed into molten silicon and then grown by extraction. As molten silicon is contained in a quartz crucible, it is contaminated with various impurities, among which is mainly oxygen. As such, oxygen is present in supersaturated concentrations in the wafers sliced from single crystal silicon grown by this method.

During the thermal treatment cycles typically employed in the fabrication of electronic devices, oxygen precipitate nucleation centers may form and ultimately grow into large oxygen clusters or precipitates. Depending upon their location, such precipitates can be beneficial or detrimental. When present in active device regions of the wafer, they can impair the operation of the device. When present outside these regions, oxygen precipitates may serve as a gettering site for metals.

Various approaches have been used to manage oxygen precipitation behavior in wafers. For example, in U.S. Pat. No. 5,994,761, Falster et al. disclose a process for installing a non-uniform concentration of vacancies in a wafer in a rapid thermal annealer whereby in a subsequent oxygen precipitation heat-treatment, oxygen precipitates form in the vacancy-rich regions but not in the vacancy-lean regions. In U.S. Pat. No. 6,336,968, Falster discloses a process in which non-oxygen precipitating wafers are prepared by rapid thermally annealing the wafers in an oxygen-containing atmosphere or by slow-cooling the wafers through the temperature range at which vacancies are relatively mobile.

While these techniques have proven useful, to-date, for typical silicon wafers, epitaxial wafer structures comprising highly doped substrates present somewhat different challenges. For example, uncontrolled oxygen precipitation in heavily doped substrates can lead to the generation of relatively large concentrations of silicon self-interstitials at high temperatures because of their emission during oxygen precipitate growth. Relatively large concentrations of silicon self-interstitials, in turn, tend to promote diffusion of dopant (or other impurities) from the highly doped substrate into the more lightly doped device layer, thereby potentially altering critical characteristics, such as avalanche breakdown voltage, in some power devices. As such, if the number of silicon interstitials near the epitaxial layer were reduced, diffusion of dopant into the device layer would be retarded.

### SUMMARY OF THE INVENTION

Among the various aspects of the present invention is a process for suppressing silicon self-interstitial diffusion from a heavily doped substrate into a lightly doped epitaxial layer in epitaxial silicon structures and the resulting structures, per se.

Briefly, therefore, one aspect of the present invention is an epitaxial silicon wafer comprising a single crystal silicon substrate that is heavily doped with an N-type dopant (N+) or a P-type dopant (P+) (i.e., having a resistivity of less than 5 mΩ*cm) and an epitaxial layer which is lightly doped with an N-type or P-type dopant (i.e., having a resistivity of greater than about 10 mΩ*cm). The heavily doped substrate comprises a silicon self-interstitial sink layer having a population of dislocation loops capable of suppressing diffusion of silicon self-interstitials into the epitaxial layer, wherein the layer of dislocation loops is at a depth of at least about 250 Å from the interface between the substrate and the epitaxial layer.

The present invention is further directed to a process for preparing such a wafer.

Other objects and features of this invention will be in part apparent and in part pointed out hereinafter.

### BRIEF DESCRIPTION OF THE DRAWINGS

FIG. 1 is a schematic representation of a highly doped silicon substrate with a lightly doped epitaxial layer wafer, wherein the substrate comprises a silicon self-interstitial sink layer comprising dislocation loops. This figure is not to scale.

FIG. 2 is a schematic representation of a highly doped silicon substrate undergoing ion implantation. This figure is not to scale.

FIG. 3 is a schematic representation of a highly doped silicon substrate after ion implantation and an anneal to form dislocation loops. This figure is not to scale.

FIG. 4 is a TEM photomicrograph showing a plan-view of dislocation loops in the silicon self-interstitial sink layer at 75,000 times magnification.

With respect to the Figures, corresponding reference characters indicate corresponding parts throughout the several views of the drawings.

### DETAILED DESCRIPTION OF THE PREFERRED EMBODIMENTS

In accordance with one aspect of the present invention, N/N+, P/P+, N/P+, or P/N+ epitaxial silicon wafers may be prepared with a region comprising dislocation loops capable of serving as a sink for silicon self-interstitials near the epitaxial layer, thereby suppressing diffusion into the epitaxial layer. This region is referred to herein as a “silicon self-interstitial sink layer,” the “interstitial sink layer” or more simply, the “sink layer.”

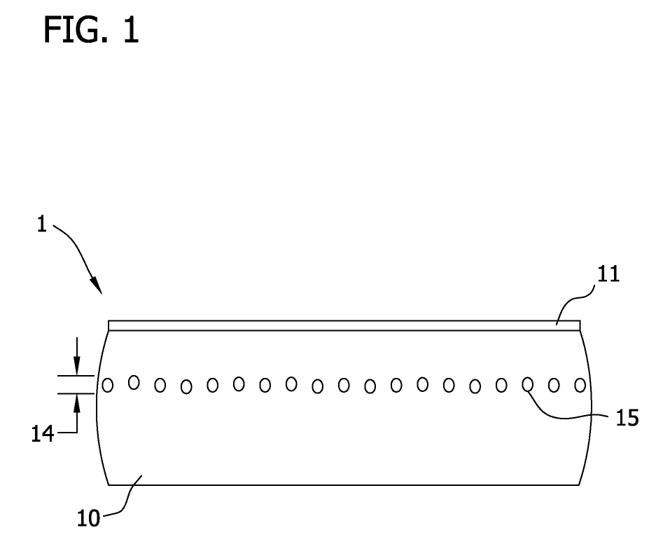

Referring to FIG. 1, epitaxial wafer 1 comprises silicon substrate 10, epitaxial layer 11, and silicon self-interstitial sink layer 14. Silicon substrate 10 is doped with an N- or P-type dopant and epitaxial layer 11 is doped with an N- or P-type dopant, with silicon substrate 10 being heavily doped relative to epitaxial layer 11. Silicon self-interstitial sink layer 14 contains a population of dislocation loops 15 that serve as a sink for silicon self-interstitial atoms that may diffuse from highly doped substrate 10 into more lightly doped epitaxial layer 11 as a result of, for example, the growth of oxygen precipitates.

In one embodiment, silicon substrate 10 has an essential absence of oxygen precipitate nuclei to further reduce the potential for diffusion of dopants and other impurities into epitaxial layer 11. That is, oxygen precipitates will not form in this embodiment during an oxygen precipitation heat treatment (e.g., annealing the wafer at a temperature of 800° C. for four hours and then at a temperature of 1000° C. for sixteen hours).

### I. Silicon Substrate

Referring again to FIG. 1, silicon substrate 10 is derived from a single crystal silicon wafer that has been sliced from a single crystal ingot grown by Czochralski crystal growing methods. The single crystal silicon wafer has a central axis; a front surface and a back surface that are generally perpendicular to the central axis; a circumferential edge; and a radius extending from the central axis to the circumferential edge. The wafer may be polished or, alternatively, it may be lapped and etched, but not polished. In addition, the wafer may have vacancy or self-interstitial point defects as the predominant intrinsic point defect. For example, the wafer may be vacancy dominated from center to edge, self-interstitial dominated from center to edge, or it may contain a central core of vacancy dominated material surrounded by an axially symmetric ring of self-interstitial dominated material.

Czochralski-grown silicon typically has an oxygen concentration within the range of about 5×10¹⁷ to about 9×10¹⁷ atoms/cm³ (ASTM standard F-121-83). In general, the single crystal silicon wafer may have an oxygen concentration falling anywhere within or even outside the range typically attainable by the Czochralski process.

In one embodiment, the single crystal silicon wafer comprises an axially symmetric region which has radial width of at least about 30% the length of the radius of the wafer and has no detectible agglomerated intrinsic point defects at a detection limit of 3×10³ defects/cm³. The axially symmetric region may contain vacancies or silicon self-interstitials as the predominant intrinsic point defect.

Depending upon the cooling rate of the single crystal silicon ingot from the melting point of silicon (about 1410° C.) through the range of about 750° C. to about 350° C., oxygen precipitate nucleation centers may form in the single crystal silicon ingot from which the silicon wafer is sliced. In one embodiment, the silicon wafer possesses such nucleation centers. In another embodiment, the silicon wafer does not.

The single crystal silicon wafer is heavily doped with one or more N-type or P-type dopants. Typical N-type dopants include phosphorous, arsenic, and antimony. In one embodiment, the dopant is phosphorous. In another embodiment, the dopant is arsenic, while in yet another, the dopant is antimony. In a further embodiment, two or more of phosphorous, arsenic, and antimony are used as dopants. Typical P-type dopants include boron, aluminum, and gallium. In one embodiment, the dopant is boron. In another, the dopant is aluminum, while in yet another, the dopant is gallium. In a further embodiment, two or more of boron, aluminum, and gallium are used as dopants. Regardless of the dopant(s), the total concentration of dopant(s) is such that the wafer has a resistivity of less than about 5 mΩ·cm, such material typically being referred to as N+ or P+ silicon. In one embodiment, the dopant concentration is sufficient to provide the wafer with a resistivity of less than about 3 mΩ·cm. In certain embodiments, resistivities of less than about 2 mΩ·cm will be preferred. In yet other embodiments, the dopant concentration is sufficient to provide the substrate with a resistivity of less than about 1 mΩ·cm.

The resistivity values noted above correspond to an N-type dopant concentration that is generally greater than about 1.24×10¹⁹ at/cm³. For example, the heavily doped wafer may have N-type dopant(s) present in a concentration greater than about 2.25×10¹⁹ at/cm³, such as greater than about 3.43×10¹⁹ at/cm³. In one preferred embodiment, the heavily doped wafer has N-type dopant(s) present in a concentration greater than about 7.36×10¹⁹ at/cm³. Similarly, the resistivity values noted above correspond to a P-type dopant concentration that is generally greater than about 2.1×10¹⁹ at/cm³. For example, the heavily doped wafer may have P-type dopant(s) present in a concentration greater than about 3.7×10¹⁹ at/cm³, such as greater than about 5.7×10¹⁹ at/cm³. In one preferred embodiment, the heavily doped wafer has P-type dopant(s) present in a concentration greater than about 1.2×10²⁰ at/cm³.

### II. Silicon Self-Interstitial Sink Layer

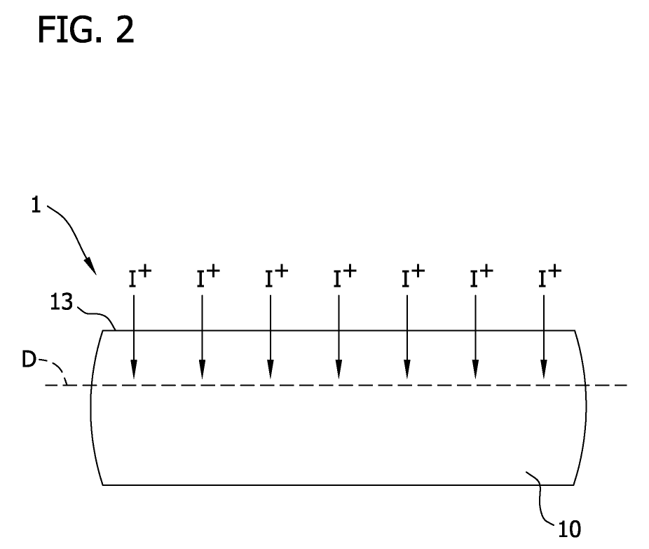

Referring again to FIG. 1, silicon self-interstitial sink layer 14 comprises a population of dislocation loops 15. In addition, interstitial sink layer 14 is present over a substantial radial width of the wafer. In the embodiment illustrated in FIG. 1, the interstitial sink layer extends across the entire diameter of substrate 10. Although this embodiment is preferred, the interstitial sink layer may not extend over the entire diameter. In general, therefore, interstitial sink layer 14 will have a radial width of at least about 10% of the length of the radius of the wafer. Typically, the radial width will be greater, for example, at least about 25%, more typically at least about 35%, and still more typically at least about 45% of the radius of the wafer. Additionally, interstitial sink layer 14 may be formed as close to face 13 as possible, so long as the dislocation loops do not extend to face 13. Interstitial sink layer 14 is preferably at a depth of at least about 100 Å, more preferably at least about 250 Å, at least about 600 Å, at least about 850 Å, or even at least about 1100 Å relative to face 13 (FIG. 2) or the corresponding interface between substrate 10 and epitaxial layer 11 (FIG. 1).

In general, dislocation loops may be formed in a series of steps comprising inducing damage to the crystal lattice structure of a substrate to create a layer of amorphous material and annealing the damaged structure. This processing forms the dislocation loops of the interstitial sink layer, typically adjacent to the layer of amorphous material. The dislocation loops developed in this manner may be, for example, perfect dislocation loops, Frank dislocation loops, or a combination thereof. Referring again to FIG. 1, silicon self-interstitial sink layer 14 lies beneath epitaxial layer 11 such that the dislocation loops within silicon self-interstitial sink layer 14 are not in contact with the substrate/epitaxial layer interface. Preferably, therefore, this series of steps is carried out in a manner to minimize any negative impact upon epitaxial layer 11 or the surface upon which epitaxial layer 11 will later be grown. This may be achieved, for example, by implanting ions through the face of a substrate and growing the epitaxial layer subsequent to ion implantation. The annealing step, whereby dislocation loops are developed in the damaged region, may thus be carried out, at least in part, before, during, or after the epitaxial deposition step.

Regardless of the means by which they are formed, the concentration of dislocation loops in the silicon self-interstitial sink layer is at least about 1×10⁸ loops/cm². Preferably, the concentration of dislocation loops in the silicon self-interstitial sink layer is at least about 1×10⁹ loops/cm², such as at least about 5×10⁹ loops/cm², or even at least about 1×10¹⁰ loops/cm².

Referring now to FIG. 2, the formation of a silicon self-interstitial sink layer in accordance with a preferred embodiment of the present invention comprises implanting ions, I⁺, through face 13 of substrate 10. Preferably, the implanted ions are electrically isoelectronic, neutral, or inert to minimize any effect upon the electronic properties of substrate 10. For example, the implanted ions are preferably selected from the group consisting of silicon, germanium, helium, neon, argon, xenon, and combinations thereof. In one embodiment, the implanted ions are silicon ions, germanium ions, or a combination thereof. In one particularly preferred embodiment, the implanted ions are silicon ions.

The ions, I⁺ in FIG. 2, are implanted to a target depth, D, relative to face 13. As a practical matter, however, some of the implanted ions will not travel this distance and others will travel an even greater distance (i.e., reach a greater depth relative to face 13). The actual ion implantation depth may vary from D by about 5%, 10%, 15%, 20%, 25%, or more. This creates a zone or layer of amorphous material containing a relatively high concentration of implanted ions at or near D, with the concentration of implanted ions decreasing from D in the direction of face 13 and in the opposite direction. Target depth, D, may also be referred to as the projected range of the implanted ions.

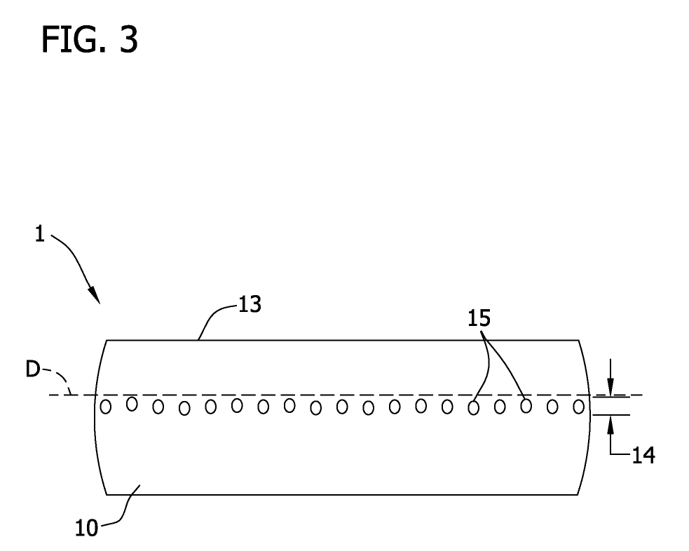

In general, the dislocation loops will form at the end of range of the implanted ions, with the end of range generally being deeper into the substrate than the projected range. That is, dislocation loops form at the edge of the layer of amorphous material farthest from face 13. As such, FIG. 3 shows that the interstitial sink layer 14, which is more fully developed in a later step, is formed approximately in the region of the wafer adjacent to the implanted ions, away from face 13. If the dislocation loops of the interstitial sink layer extend to face 13, they may jeopardize the deposition of a robust, consistent epitaxial layer or they may lead to propagation of defects, such as threading dislocation defects, into the epitaxial layer.

Accordingly, target depth, D, is such that the subsequently formed dislocation loops do not extend to the surface upon which the epitaxial layer is formed or to the corresponding substrate/epitaxial layer interface. This target depth may be very close to or just below face 13, but D is more typically at least about 250 Å. In one embodiment, D is at least about 500 Å. In another embodiment, D is at least about 750 Å. In a further embodiment, D is about 1000 Å. In yet a further embodiment, D is greater than about 1000 Å.

Implantation depth may be affected, at least in part, by the ionic species implanted, since lighter ions tend to penetrate further into substrate 10 for a given implantation energy. Thus, for example, at an implant energy of 50 keV, silicon ions will have an average implant depth of about 750 Å, whereas germanium ions will have an average implant depth of 400 Å. In general, ions are preferably implanted using at least about 30 keV, such as at least about 40 keV, or even at least about 50 keV. In one application, ions are implanted using at least about 45 keV and less than about 55 keV.

Generally, dislocation loops form at the end of range of the implanted ions upon subsequent anneal if sufficient energy is used to implant a sufficient concentration of ions to form an amorphous layer of silicon. Typically, the dislocation loops may form at a depth of about 100 Å to 300 Å below the implanted ions, although the exact depth may be more or less. In general, it is more difficult to form amorphous material using lower mass elements. Accordingly, a much higher concentration of low mass elements must be used to induce sufficient damage, whereas lower concentrations of high mass elements are sufficient to form amorphous silicon. For example, when the implanted ions are silicon ions, the implanted dose is preferably at least about 2×10¹⁴ atoms/cm², such as at least about 5×10¹⁴ atoms/cm², or even at least about 1×10¹⁵ atoms/cm². In one preferred embodiment, the implanted ion dose is at least about 2×10¹⁵ atoms/cm². By comparison, when the implanted ions are the higher mass germanium ions, the implanted dose is preferably at least about 6×10¹³ atoms/cm², such as at least about 1×10¹⁴ atoms/cm², or even at least about 5×10¹⁴ atoms/cm². In one preferred embodiment, the implanted ion dose is at least about 1×10¹⁵ atoms/cm².

The implanted substrate is then annealed for a time and at a temperature to convert the crystallographic damage caused during ion implantation into dislocation loops 15, as shown in FIG. 2. In general, the annealing temperature is at least 750° C. Preferably, the annealing temperature is less than about 950° C. In a preferred embodiment, therefore, implanted substrate 10 is annealed at a temperature of about 800° C. to about 925° C. For example, implanted substrate 10 may be annealed at about 900° C. In general, implanted substrate 10 will be annealed for at least a few seconds (i.e., at least about 3, 4, 5, or even 10 seconds), or even a few minutes (i.e., at least about 2, 3, 4, 5, or even 10 minutes). More typically, implanted substrate 10 will be annealed for at least about 30 minutes, such as at least about 60 minutes, or even at least about 90 minutes. In one embodiment, implanted substrate 10 will be annealed for about 120 minutes.

In one embodiment, the ion implantation and anneal process is followed by one or more successive ion implantation and anneal processes, typically with successively lower implantation energy levels for the same ion, or with different ion(s). In this embodiment, the silicon self-interstitial sink layer comprises multiple strata of dislocation loops, which may increase the capacity for silicon self-interstitial consumption.

### III. Epitaxial Layer

Referring again to FIG. 1, epitaxial layer 11 is deposited or grown on a surface of the annealed silicon wafer by means generally known in the art, the surface preferably having an absence of dislocation loops. In one embodiment, the average thickness of the epitaxial layer is at least about 5 cm. In one embodiment, epitaxial layer 11 is grown after the implanted substrate is annealed to develop the dislocation loops. In another embodiment, epitaxial layer 11 is grown as the implanted substrate is annealed to develop the dislocation loops. In yet another embodiment, the implanted wafer is partially annealed to develop the dislocation loops before or after the growth of the epitaxial layer. Advantageously, therefore, the annealing step and the epitaxial growth step may be carried out in the same apparatus.

Regardless of when it is formed, epitaxial layer 11 is preferably grown by chemical vapor deposition; such processes are described, for example, in U.S. Pat. No. 5,789,309. Doping of the epitaxial layer may take place after or during the epitaxial layer growth process. Regardless of the doping method, the resulting epitaxial layer has a dopant concentration to provide the epitaxial layer with a resistivity of at least about 10 mΩ·cm, such as at least about 100 mΩ·cm. For example, the epitaxial layer will typically have a resistivity of between about 100 mΩ·cm and about 100 Ω·cm. In one application, the epitaxial layer will have a resistivity of between about 300 mΩ·cm and about 10 Ω·cm.

As an alternative means of characterizing the epitaxial layer, the epitaxial layer will typically have a dopant concentration of less than about 4.8×10¹⁸ at/cm³, such as between about 4.3×10¹³ at/cm³ and about 7.8×10¹⁶ at/cm³. In one application, the epitaxial layer has a dopant concentration between about 4.4×10¹⁴ at/cm³ and about 1.9×10¹⁶ at/cm³.

The epitaxial layer is doped, as described, with one or more of either N-type or P-type dopants. In an embodiment wherein N-type doping is preferred, the N-type dopants are selected, for example, from the group consisting of phosphorous, arsenic, and antimony. Typically, the N-type dopant will be phosphorous, arsenic, or both phosphorous and arsenic. In one embodiment, the dopant is phosphorous. In another, the dopant is arsenic. In yet another embodiment, both phosphorous and arsenic are used as dopants. In an embodiment wherein P-type doping is preferred, the P-type dopants are selected, for example, from the group consisting of boron, aluminum, and gallium. In one embodiment, the P-type dopant is boron.

One advantage of epitaxial deposition is that existing epitaxial growth reactors can be used in conjunction with a direct dopant feed during epitaxial growth. That is, the dopant can be mixed with the carrier gas to dope the deposited epitaxial layer.

### IV. Controlling Oxygen Precipitation

In one embodiment, the wafer is also subjected to an oxygen precipitate nuclei dissolution step to improve oxygen precipitation behavior in the substrate. Stated differently, restricting or preventing oxygen precipitation in the substrate may yield an even greater degree of control over diffusion of dopant (and other impurities) into the more lightly doped epitaxial layer. The dissolution step may be performed before, after, or as part of the formation of the silicon self-interstitial sink layer, so long as the process parameters do not compromise the integrity of the dislocation loops. Preferably, this process is performed before the silicon self-interstitial sink layer is formed.

The highly doped wafer is subjected to a heat treatment step to cause dissolution of any pre-existing oxygen clusters and any pre-existing oxidation-induced stacking faults (OISF) nuclei in the substrate. Preferably, this heat treatment step is carried out in a rapid thermal annealer (RTA) in which the wafer is rapidly heated to a target temperature, then annealed at that temperature for a relatively short period of time. In general, the wafer is rapidly heated to a temperature in excess of 1150° C., preferably at least 1175° C., typically at least about 1200° C., and, in some embodiments, to a temperature of about 1200° C. to 1275° C. The wafer will generally be maintained at this temperature for at least one second, typically for at least several seconds (e.g., at least 3), and potentially for several tens of seconds (such as between about 10 and about 60 seconds, e.g., 20, 30, 40, or 50 seconds) depending upon the concentration, type, and size of any pre-existing defects.

The rapid thermal anneal may be carried out in any of a number of commercially available RTA furnaces in which wafers are individually heated by banks of high power lamps. Rapid thermal annealer furnaces are capable of rapidly heating a silicon wafer, e.g., they are capable of heating a wafer from room temperature to 1200° C. in a few seconds. One such commercially available RTA furnace is the 3000 RTP available from Mattson Technology (Freemont, Calif.).

In addition to dissolving a variety of pre-existing oxygen clusters and OISF nuclei, the annealing step will increase the number density of crystal lattice vacancies in the wafer. Information obtained to date suggests that certain oxygen-related defects, such as ring OISF, are high temperature nucleated oxygen agglomerates catalyzed by the presence of a high concentration of vacancies. Furthermore, in high vacancy regions, oxygen clustering is believed to occur rapidly at elevated temperatures, as opposed to regions of low vacancy concentration where behavior is more similar to regions in which oxygen precipitate nucleation centers are lacking. Because oxygen precipitation behavior is influenced by vacancy concentration, therefore, controlling the density of vacancies in the heat-treated wafer limits or even avoids oxygen precipitation in a subsequent oxygen precipitation heat treatment. Advantageously, the (number) density of vacancies in the annealed wafer can be controlled by limiting the cooling rate from the annealing temperature, by including a sufficient partial pressure of oxygen in the annealing atmosphere, or by doing both.

The vacancy concentration in the annealed wafer may be controlled, at least in part, by controlling the atmosphere in which the heat-treatment is carried out. Experimental evidence obtained to date suggests that the presence of a significant amount of oxygen suppresses the vacancy concentration in the annealed wafer. Without being held to any particular theory, it is believed that the rapid thermal annealing treatment in the presence of oxygen results in the oxidation of the silicon surface, creating an inward flux of silicon self-interstitials. This inward flux of self-interstitials has the effect of gradually altering the vacancy concentration profile by causing Frankel pair recombinations to occur, beginning at the surface and then moving inward.

Regardless of the mechanism, the annealing step is carried out in the presence of an oxygen-containing atmosphere in one embodiment. That is, the anneal is carried out in an atmosphere containing oxygen gas (O₂), water vapor, or an oxygen-containing compound gas which is capable of oxidizing an exposed silicon surface. The atmosphere may thus consist entirely of oxygen or oxygen compound gas, or it may additionally comprise a non-oxidizing gas, such as argon. However, when the atmosphere is not entirely oxygen, the atmosphere will preferably contain a partial pressure of oxygen of at least about 0.001 atmospheres (atm.), or 1,000 parts per million atomic (ppma). More preferably, the partial pressure of oxygen in the atmosphere will be at least about 0.002 atm. (2,000 ppma), still more preferably 0.005 atm. (5,000 ppma), and still more preferably 0.01 atm. (10,000 ppma).

Intrinsic point defects (vacancies and silicon self-interstitials) are capable of diffusing through single crystal silicon, with the rate of diffusion being temperature dependent. The concentration profile of intrinsic point defects, therefore, is a function of the diffusivity of the intrinsic point defects and the recombination rate as a function of temperature. For example, the intrinsic point defects are relatively mobile at temperatures in the vicinity of the temperature at which the wafer is annealed in the rapid thermal annealing step, whereas they are essentially immobile for any commercially practical time period below or at temperatures of as much as 700° C. Experimental evidence obtained to-date suggests that the effective diffusion rate of vacancies slows considerably, such that vacancies can be considered to be immobile for any commercially practical time period, at temperatures less than about 700° C. and perhaps less than about 800° C., 900° C., or even 1,000° C.

Accordingly, in one embodiment the concentration of vacancies in the annealed wafer is controlled, at least in part, by controlling the cooling rate of the wafer through the temperature range in which vacancies are relatively mobile. Such control is exercised for a time period sufficient to reduce the number density of crystal lattice vacancies in the cooled wafer prior to cooling the wafer below the temperature range in which vacancies are relatively mobile. As the temperature of the annealed wafer is decreased through this range, the vacancies diffuse to the wafer surface and become annihilated, leading to a change in the vacancy concentration profile. The extent of such change depends on the length of time the annealed wafer is maintained at a temperature within this range and the magnitude of the temperature, with greater temperatures and longer diffusion times generally leading to increased diffusion. In general, the average cooling rate from the annealing temperature to the temperature at which vacancies are practically immobile (e.g., about 950° C.) is preferably no more than 20° C. per second, more preferably no more than about 10° C. per second, and still more preferably no more than about 5° C. per second.

Alternatively, the temperature of the annealed wafer following the high temperature anneal may be reduced quickly (e.g., at a rate greater than about 20° C./second) to a temperature of less than about 1150° C. but greater than about 950° C., and then held for a time period that is dependent upon the holding temperature. For example, several seconds (e.g., at least about 2, 3, 4, 6 or more) may be sufficient for temperatures near 1150° C., whereas several minutes (e.g., at least about 2, 3, 4, 6 or more) may be required for temperatures near 950° C. to sufficiently reduce the vacancy concentration.

Once the annealed wafer is cooled to a temperature outside the range of temperatures at which crystal lattice vacancies are relatively mobile, the cooling rate does not appear to significantly influence the precipitating characteristics of the wafer and, as such, does not appear to be narrowly critical.

Conveniently, the cooling step may be carried out in the same atmosphere in which the heating step is carried out. Suitable atmospheres include, e.g., nitriding atmospheres (i.e., atmospheres containing nitrogen gas (N₂) or a nitrogen-containing compound gas that is capable of nitriding an exposed silicon surface, such as ammonia); oxidizing (oxygen-containing) atmospheres; non-oxidizing, non-nitriding atmospheres (such as argon, helium, neon, carbon dioxide); and combinations thereof.

While the rapid thermal treatments employed herein may result in the out-diffusion of a small amount of oxygen from the surface of the front and back surfaces of the wafer, the resulting annealed wafer has a substantially uniform interstitial oxygen concentration as a function of distance from the silicon surface. For example, the annealed wafer will have a substantially uniform concentration of interstitial oxygen from the center of the wafer to regions of the wafer that are within about 15 microns of the silicon surface, more preferably from the center of the silicon to regions of the wafer that are within about 10 microns of the silicon surface, even more preferably from the center of the silicon to regions of the wafer that are within about 5 microns of the silicon surface, and most preferably from the center of the silicon to regions of the wafer that are within about 3 microns of the silicon surface. In this context, a substantially uniform oxygen concentration shall mean a variance in the oxygen concentration of no more than about 50%, preferably no more than about 20%, and most preferably no more than about 10%.

In one embodiment, the epitaxial layer is formed in conjunction with the annealing step detailed above. In this embodiment, the annealing step is carried out in the epitaxial reactor. Upon completing the annealing step and epitaxial layer formation, the cooling atmosphere, cooling rate, or both the cooling atmosphere and rate are controlled as detailed above. That is, in one variation of this embodiment, the atmosphere after the anneal and epitaxial layer formation is an oxygen-containing atmosphere that is capable of oxidizing an exposed silicon surface. Specifically, the atmosphere will preferably contain a partial pressure of oxygen of at least about 0.001 atmospheres (atm), or 1,000 parts per million atomic (ppma). More preferably, the partial pressure of oxygen in the atmosphere will be at least about 0.002 atm (2,000 ppma), still more preferably 0.005 atm (5,000 ppma), and still more preferably 0.01 atm (10,000 ppma).

In other variations of this embodiment, the cooling rate of the wafer is controlled with or without controlling the cooling atmosphere. Specifically, the cooling rate is controlled such that the average cooling rate from the annealing temperature to the temperature at which vacancies are practically immobile (e.g., about 950° C.) is preferably no more than 20° C. per second, more preferably no more than about 10° C. per second, and still more preferably no more than about 5° C. per second. Alternatively, the temperature may be reduced quickly (e.g., at a rate greater than about 20° C./second) to a temperature of less than about 1150° C. but greater than about 950° C., and then held for a time period between several seconds to several minutes, depending upon the holding temperature. For example, at least about 2, 3, 4, 6 seconds or more may be sufficient for temperatures near 1150° C., whereas at least about 2, 3, 4, 6 minutes or more may be required for temperatures near 950° C.

### V. Polysilicon Layer

In one embodiment, a polysilicon layer is deposited on the backside of the highly doped substrate before the annealing step described above. The grain boundaries of the polysilicon layer serve as a gettering site for dopant. In general, the polysilicon layer may be deposited by any means conventionally known in the art. For example, the polysilicon layer may be deposited by chemical vapor deposition using silane (SiH₄) gas and arsenic doping, as more fully described in U.S. Pat. Nos. 5,792,700 or 5,310,698.

Silicon structures manufactured according to this invention may be used in various technologies. For example, the silicon structure of this invention is suitable for use in the manufacture of power devices, such as power diodes, thyristors, and, in particular, power MOSFETs and JFETs. This list is in no way intended to be restrictive or comprehensive.

### VI. Example

The following non-limiting example is provided to further illustrate and explain the present invention. The invention should not be limited to any of the details provided herein.

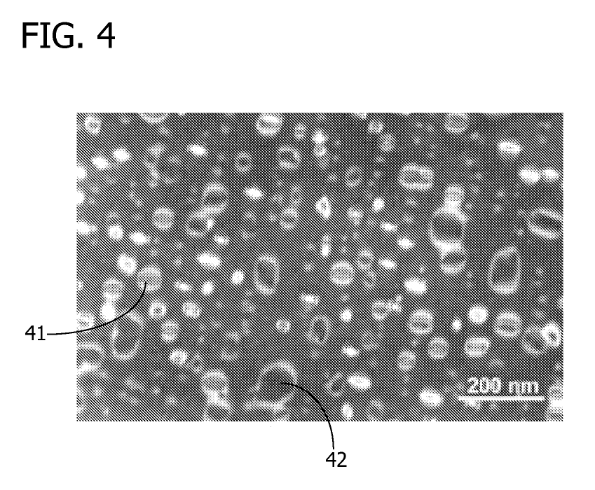

A single crystal silicon wafer doped with about 7.86×10¹⁹ phosphorus atoms/cm³ is exposed to an ion implantation process wherein silicon ions are implanted into the front surface of the wafer. The silicon ions are implanted with an energy level of 50 keV such that the substrate has a concentration of about 2×10¹⁵ atoms/cm² at an average distance of about 1000 Å from the front surface. The ion implanted, highly doped substrate is then annealed at about 900° C. for about 120 minutes to form about 1.3×10¹⁰ dislocation loops/cm² at about 1000 Å from the front surface. An epitaxial layer is then formed on the front surface of the substrate, the epitaxial layer being doped with less than about 4.8×10¹⁸ phosphorus atoms/cm³. Transmission electron microscopic analysis at 75,000 times magnification reveals the presence of the dislocation loops, as seen in FIG. 4. Frank dislocation loops 41 and perfect dislocation loops 42 may be observed.

When introducing elements of the present invention or the preferred embodiments(s) thereof, the articles “a”, “an”, “the”, and “said” are intended to mean that there are one or more of the elements. The terms “comprising”, “including”, and “having” are intended to be inclusive and mean that there may be additional elements other than the listed elements. Moreover, unless explicitly noted otherwise, reference to the heavily doped substrate as “N+” or “P+” should be understood to also refer to substrates having doping levels conventionally referred to as N++ and N+++ or P++ and P+++, respectively. Also, unless explicitly noted otherwise, reference to the lightly doped epitaxial layer as “N” or “P” should be understood to also refer to substrates having doping levels conventionally referred to as N− or P−, respectively.

In view of the above, it will be seen that the several objects of the invention are achieved and other advantageous results attained.

As various changes could be made in the above products and methods without departing from the scope of the invention, it is intended that all matter contained in the above description and shown in the accompanying drawings shall be interpreted as illustrative and not in a limiting sense. The above description of the various embodiments is intended only to acquaint others skilled in the art with the invention, its principles, and its practical application so that others skilled in the art may adapt and apply the invention in its numerous forms, as may be best suited to the requirements of a particular use.

What is claimed is:

1. A process for preparing an epitaxial silicon wafer, the process comprising:
forming a layer of dislocation loops in a highly doped single crystal silicon substrate, the highly doped silicon substrate being the slice of an ingot grown by the Czochralski method having a central axis, a front surface and a back surface that are generally perpendicular to the central axis, a circumferential edge joining the front and back surfaces, a radius extending from the central axis to the circumferential edge, a resistivity of less than 5 mΩ*cm; and wherein the dislocation loops do not extend to the front surface; and
depositing an epitaxial silicon layer on the front surface of the highly doped silicon substrate to form the epitaxial silicon wafer, the epitaxial layer having a resistivity of greater than about 10 mΩ*cm.

2. The process of claim 1 wherein the dislocation loops are formed by an ion implantation of the highly doped single crystal silicon substrate and an anneal of at least about 750° C.

3. The process of claim 2 wherein the implanted ions are selected from the group consisting of silicon, germanium, helium, neon, argon, xenon, and a combination thereof.

4. The process of claim 2 wherein the ion implantation is carried out at an energy level of at least about 30 keV.

5. The process of claim 2 wherein the ion implantation step implants at least about 6×10¹³ atoms/cm².

6. The process of claim 2 wherein the anneal is carried out for at least about 3 seconds.

7. The process of claim 1 wherein the highly doped silicon substrate comprises an N-type dopant.

8. The process of claim 7 wherein the highly doped silicon substrate comprises a dopant selected from the group consisting of P, As, Sb, and combinations thereof.

9. The process of claim 1 wherein the highly doped silicon substrate comprises a P-type dopant.

10. The process of claim 9 wherein the highly doped silicon substrate comprises a dopant selected from the group consisting of B, Al, Ga, and combinations thereof.

11. The process of claim 1 wherein the epitaxial layer comprises an N-type dopant.

12. The process of claim 11 wherein the epitaxial layer comprises a dopant selected from the group consisting of P, As, and combinations thereof.

13. The process of claim 1 wherein the epitaxial layer comprises a P-type dopant.

14. The process of claim 13 wherein the epitaxial layer comprises a dopant selected from the group consisting of B, Al, Ga, and combinations thereof.

15. The process of claim 1 wherein the epitaxial layer is deposited to a thickness of at least about 5 cm.

16. The process of claim 1 further comprising depositing a layer of polysilicon on the back surface of the highly doped single crystal silicon substrate before the annealing step.

17. The process of claim 1 wherein the layer is at a depth of at least about 100 Å from the front surface of the highly doped silicon substrate.

18. The process of claim 1 wherein the layer of dislocation loops has a concentration of at least about 1×10⁸ loops/cm².

19. The process of claim 1 wherein the layer of dislocation loops has a radial width of at least about 10% of the radius.

20. An epitaxial silicon wafer comprising:
a highly doped single crystal silicon substrate that is a slice of an ingot grown by the Czochralski method having: a central axis, a front surface and a back surface that are generally perpendicular to the central axis, a circumferential edge joining the front and back surfaces, a radius extending from the central axis to the circumferential edge, and a resistivity of less than 5 mΩ*cm;
an epitaxial layer on the front surface of the highly doped silicon substrate, forming the epitaxial silicon wafer, wherein the epitaxial layer has a resistivity of greater than about 10 mΩ*cm; and
a layer of dislocation loops in the substrate, wherein the dislocation loops do not extend to the interface between the substrate and the epitaxial layer.

21. The wafer of claim 20 wherein the highly doped silicon substrate comprises an N-type dopant.

22. The wafer of claim 21 wherein the highly doped silicon substrate comprises a dopant selected from the group consisting of P, As, Sb, and combinations thereof.

23. The wafer of claim 20 wherein the highly doped silicon substrate comprises a P-type dopant.

24. The wafer of claim 23 wherein the highly doped silicon substrate comprises a dopant selected from the group consisting of B, Al, Ga, and combinations thereof.

25. The wafer of claim 20 wherein the epitaxial layer comprises an N-type dopant.

26. The wafer of claim 25 wherein the epitaxial layer comprises a dopant selected from the group consisting of P, As, and combinations thereof.

27. The wafer of claim 20 wherein the epitaxial layer comprises a P-type dopant.

28. The wafer of claim 27 wherein the epitaxial layer comprises a dopant selected from the group consisting of B, Al, Ga, and combinations thereof.

29. The wafer of claim 20 wherein the highly doped silicon substrate is substantially free from oxygen precipitate nuclei.

30. The wafer of claim 20 wherein the layer of dislocation loops is at a depth of at least about 100 Å from the interface between the substrate and the epitaxial layer.

31. The wafer of claim 20 wherein the layer of dislocation loops has a concentration of at least about 1×10⁸ loops/cm².

32. The wafer of claim 20 wherein the layer of dislocation loops has a radial width of at least about 10% of the radius of the substrate
